(19) United States
(12) Patent Application Publication
(10) Pub. No.: US 2026/0164941 A1
(43) Pub. Date: Jun. 11, 2026

(54) DISPLAY DEVICE AND METHOD OF MANUFACTURING THE SAME

(71) Applicant: LG Display Co., Ltd., Seoul (KR)

(72) Inventors: Yosup SIM, Paju-si (KR); Seongjoo LEE, Paju-si (KR); Yongmin KIM, Paju-si (KR); Sookhee JEONG, Paju-si (KR)

(73) Assignee: LG Display Co., Ltd., Seoul (KR)

(21) Appl. No.: 19/356,688

(22) Filed: Oct. 13, 2025

(30) Foreign Application Priority Data
Dec. 9, 2024 (KR) 10-2024-0181946

(51) Int. Cl. H10K 59/122; H10K 59/124

(52) U.S. Cl. CPC H10K 59/122; H10K 59/124

(57) ABSTRACT

A display device includes: a substrate, a first planarization layer disposed on the substrate, and a second planarization layer disposed on the first planarization layer having an opening. A pixel electrode is disposed on the first planarization layer within the opening and extends along an inner side surface of the second planarization layer. A bank is disposed on the pixel electrode and has a hole smaller than the opening. The edge of the opening includes a specific curved region, and the opening is defined by the inner side surface of the second planarization layer. A specific portion of the inner side surface of the second planarization layer corresponding to the specific curved region may include at least one step to improve light extraction efficiency, enhance luminance uniformity, and provide a coating path for an organic encapsulation layer.

### CROSS REFERENCE TO RELATED APPLICATION

This application claims priority from Korean Patent Application No. 10-2024-0181946, filed on Dec. 9, 2024, which is hereby incorporated by reference for all purposes as if fully set forth herein.

### BACKGROUND

### Technical Field

Embodiments of the present disclosure relate to a display device and method of manufacturing the same.

### Description of the Related Art

Among display devices, there are self-emissive display devices in which a display panel emits light by itself. In a self-emissive display device, the display panel may include a light-emitting device in each sub-pixel.

Meanwhile, light generated from the light-emitting device of the display panel exits to the outside of the display panel through various components of the display panel. However, among the light generated from the light-emitting device, some light may be trapped inside the display panel without exiting to the outside. As the amount of light that fails to exit and remains trapped inside the display panel increases, the luminance of the corresponding sub-pixel may decrease. Accordingly, the quality of an image displayed on the display panel may eventually deteriorate. Additionally, when external light is reflected by the display panel, the image quality may also degrade.

### BRIEF SUMMARY

The present disclosure describes a display device structure that improves light extraction efficiency and image uniformity through an optical side mirror design. A stepped second planarization layer with inclined sidewalls allows the pixel electrode to reflect light outward, creating both a primary emission area (e.g., first emission area EA1) and a secondary emission area (e.g., additional second emission area EA2) from reflected light. Corner regions, which normally suffer from reduced luminance, are addressed using a multi step geometry at the planarization layer and bank sidewalls, enabling uniform brightness across edges and corners while reducing power consumption.

The manufacturing method uses controlled light exposure techniques such as half tone masking to form these multi step geometries with precision, ensuring reproducibility for mass production. This stepped design also improves the coating uniformity of the organic encapsulation layer, preventing defects that could compromise moisture protection or decrease device reliability.

The structure further incorporates flexible and foldable display capabilities with crack prevention patterns for durability and a built in touch sensor layer aligned along inclined surfaces to maintain optical clarity. Together with a microcavity effect created by reflective and transparent electrode layers, the design enhances luminance, color purity, and low power performance, making it suitable for next generation foldable, wearable, and mobile displays.

For example, various embodiments of the present disclosure may provide a display device having a structure that improves light extraction efficiency.

Embodiments of the present disclosure may provide a display device having a structure that improves coating uniformity by providing a spreading path for an organic encapsulation layer.

The technical benefits of embodiments of the present disclosure are not limited to those mentioned above, and other benefits not mentioned will be clearly understood by those skilled in the art based on the following descriptions.

Embodiments of the present disclosure may provide a display device comprising a substrate; a first planarization layer disposed on the substrate; a second planarization layer disposed on the first planarization layer and having an opening; a pixel electrode disposed on the first planarization layer within the opening and extending along an inner side surface of the second planarization layer; and a bank disposed on the pixel electrode and having a hole smaller than the opening, wherein an edge of the opening includes a specific curved region, the opening is defined by the inner side surface of the second planarization layer, and a specific portion of the inner side surface of the second planarization layer corresponding to the specific region includes at least one step.

Embodiments of the present disclosure may provide a method of manufacturing a display device comprising: forming a first planarization layer on a substrate; forming a second planarization layer having an opening on the first planarization layer; forming a pixel electrode disposed on the first planarization layer within the opening and extending along a side surface of the second planarization layer outside the opening; and forming a bank on the pixel electrode, the bank having a hole smaller than the opening, wherein forming the second planarization layer includes forming at least one step at a corner portion of the inner side surface of the second planarization layer by adjusting the amount of light exposure.

According to embodiments of the present disclosure, light generated in the emission layer of the light-emitting device may be reflected at an inclined surface of the pixel electrode and emitted to the outside by arranging the second planarization layer with a step and an inclined surface and by extending the pixel electrode along the inclined surface. Accordingly, light extraction efficiency may be improved.

According to embodiments of the present disclosure, light extraction efficiency may be further enhanced by the stepped structure of the second planarization layer.

According to embodiments of the present disclosure, the enhanced light extraction efficiency may enable obtaining a desired luminance with reduced driving time or driving voltage of the light-emitting device, thus allowing for a low-power design that reduces power consumption and extends the lifespan of the light-emitting device.

According to embodiments of the present disclosure, steps formed in the bank corresponding to the steps formed in the second planarization layer may prevent the organic encapsulation layer from being uncoated or abnormally coated.

The effects of the embodiments of the present disclosure are not limited to those mentioned above, and other effects not mentioned will be clearly understood by those skilled in the art based on the descriptions of the claims.

### BRIEF DESCRIPTION OF THE SEVERAL VIEWS OF THE DRAWINGS

The present disclosure will be more fully understood from the following detailed description and the accompanying drawings. The detailed description and drawings are provided for illustrative purposes only and are not intended to limit the scope of the present specification.

FIG. 1 is a plan view of a display panel according to embodiments of the present disclosure.

FIG. 2 is a cross-sectional view illustrating the structure of the display panel of FIG. 1 according to embodiments of the present disclosure.

FIG. 3 is a cross-sectional view of a display panel according to embodiments of the present disclosure.

FIG. 4 illustrates light emission of a sub-pixel region according to embodiments of the present disclosure.

FIG. 5 is a plan view of a sub-pixel region according to embodiments of the present disclosure.

FIG. 6 is a cross-sectional view of FIG. 5 according to embodiments of the present disclosure.

FIG. 7 illustrates light emission of a sub-pixel region according to embodiments of the present disclosure.

FIG. 8 is a cross-sectional view of a sub-pixel region according to embodiments of the present disclosure.

FIG. 9 is a flowchart illustrating a method of manufacturing a sub-pixel region according to embodiments of the present disclosure.

FIG. 10 to FIG. 11 illustrate a method of manufacturing a sub-pixel region according to embodiments of the present disclosure.

FIG. 12 to FIG. 16 are plan views of a sub-pixel region according to embodiments of the present disclosure.

FIG. 17 illustrates light emission of a sub-pixel region according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Various embodiments of the present specification will be described in detail with reference to the accompanying drawings.

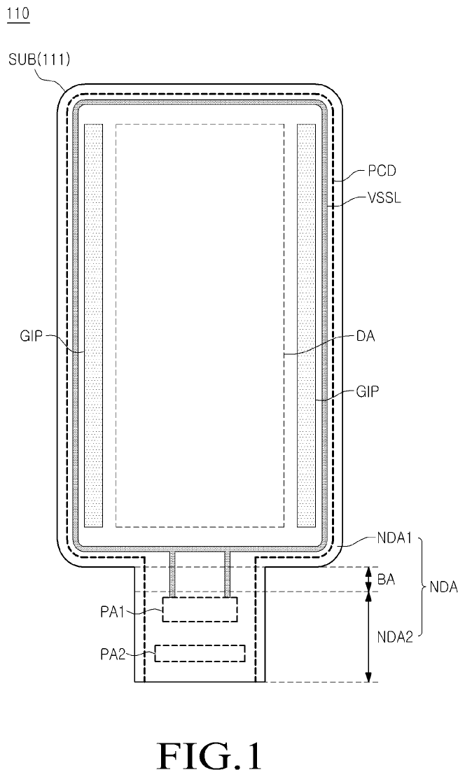

FIG. 1 is a view illustrating an example of a bending structure and wiring structure in a plan view of a display panel 110 according to embodiments of the present disclosure.

Referring to FIG. 1, a substrate 111 of the display panel 110 according to embodiments of the present disclosure may include a display area DA and a non-display area NDA. The display area DA and the non-display area NDA may be referred to as regions of the display panel 110.

All wirings and electrodes are formed on the substrate 111. In a display device according to embodiments of the present disclosure, the substrate 111 may be a flexible substrate capable of bending. In the present disclosure, “bending” may have the same meaning as “folding” or “flexible.”

The non-display area NDA is a region in which no image is displayed and may correspond to a region excluding the display area DA. Sub-pixels SP are not disposed in the non-display area NDA. However, at least one dummy sub-pixel not directly involved in image display may be disposed in the non-display area NDA.

The non-display area NDA may include a first non-display area NDA1, a bending area BA, and a second non-display area NDA2.

The first non-display area NDA1 may be located around the display area DA and may be the region closest to the display area DA among the first non-display area NDA1, the bending area BA, and the second non-display area NDA2.

The second non-display area NDA2 may include pad areas PA1 and PA2, in which various pads are arranged, and may be the region farthest from the display area DA among the first non-display area NDA1, the bending area BA, and the second non-display area NDA2.

The bending area BA is a region where the substrate 111 is bent, and may be located between the first non-display area NDA1 and the second non-display area NDA2.

The substrate 111 may include a display area DA in which an image is displayed and a non-display area NDA, which is an outer area of the display area DA. A plurality of sub-pixels SP may be disposed in the display area DA. The non-display area NDA may include a gate in panel GIP region in which a gate driving circuit of a GIP type is formed, the bending area BA through which various wirings pass and to which a data driving circuit is electrically connected, and the second non-display area NDA2.

For example, the GIP region may be located in a left and/or right outer area of the display area DA. The non-display area NDA may be located in an upper outer area or a lower outer area of the display area DA. The second non-display area NDA2 may be more peripheral than the bending area BA and may include the pad areas PA1 and PA2 electrically connected to a circuit structure such as a printed circuit board.

As described above, the substrate 111 may include a bending area BA that is folded, and the folded bending area BA may be located under a non-folded portion. The bending area BA may be a part of the non-display area NDA and may be located between a driving circuit region electrically connected to a data driving circuit and the display area DA.

According to the structure of the sub-pixel SP, to drive the sub-pixel SP, a plurality of driving voltage lines DVL for supplying a driving voltage VDD to the sub-pixel SP, and at least one base voltage line VSSL for applying a base voltage VSS to a common electrode CE of a light-emitting device ED in each sub-pixel SP, may be further disposed on the substrate 111.

Referring to FIG. 1, for example, the plurality of driving voltage lines DVL may be arranged in a column direction, but are not limited thereto. In order to efficiently deliver the driving voltage VDD through the plurality of driving voltage lines DVL, a driving voltage pattern integrated with or electrically connected to the plurality of driving voltage lines DVL may be disposed in the non-display area NDA.

The plurality of driving voltage lines DVL may be electrically connected through the driving voltage pattern to a data driving circuit or a printed circuit board connected to the pad areas PA1 and PA2 via the bending area BA.

At least one base voltage line VSSL may be disposed in the non-display area NDA so as to surround an outer region of the display area DA to efficiently deliver the base voltage VSS. Additionally, the at least one base voltage line VSSL may be electrically connected to a data driving circuit or a printed circuit board connected to a driving circuit region via the bending area BA.

The substrate 111 may include a crack prevention pattern PCD. The crack prevention pattern PCD may be formed outside the base voltage line VSSL in the non-display area NDA, but is not limited thereto.

For example, the crack prevention pattern PCD may be a pattern formed to prevent cracks in wirings passing through the substrate 111, and may be formed in a zigzag pattern, but is not limited thereto.

For example, some of the signal lines passing through the bending area BA may become cracked (electrically open) or short-circuited with adjacent signal lines when the bending area BA is bent. In such cases, accurate signals may not be transmitted through the cracked or short-circuited signal lines, which may cause problems in display driving, resulting in improper image display and significantly deteriorated image quality. Accordingly, the crack prevention pattern PCD may be included to prevent such issues, but is not limited thereto.

The display panel 110 described above includes a flexible substrate 111, and by bending the bending area BA to which the data driving circuit is connected, a portion of the substrate 111 is folded backward. The folded bending area BA becomes a portion that cannot display an image and is not visible from the front. Accordingly, by utilizing the bending structure and wiring arrangement structure shown in FIG. 1, the bezel size of the display device may be significantly reduced, and a visually satisfying narrow bezel design may be provided.

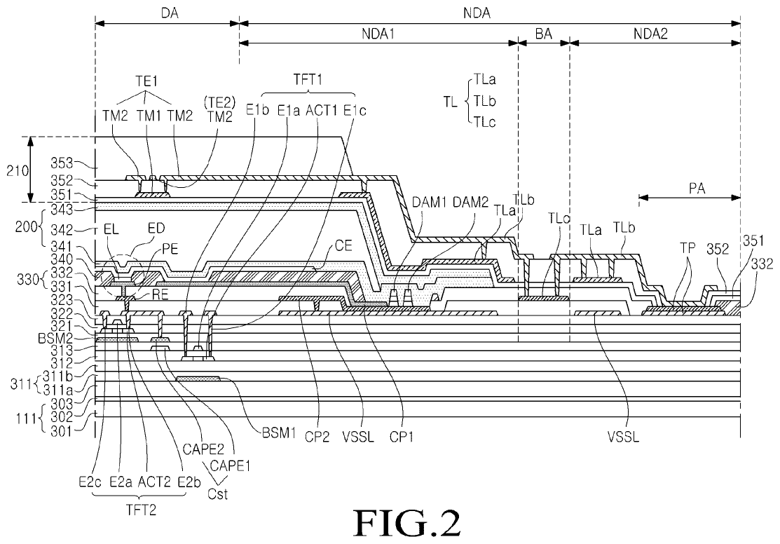

FIG. 2 is a cross-sectional view illustrating an example structure of the display panel 110 of FIG. 1 according to embodiments of the present disclosure.

Referring to FIG. 2, the display panel 110 according to embodiments of the present disclosure may include the substrate 111, a transistor portion, a light-emitting device portion, and an encapsulation portion, but the embodiments of the present disclosure are not limited thereto.

The substrate 111 may be a single-layer or a multilayer substrate. When the substrate 111 is a multilayer structure, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer; however, the embodiments of the present disclosure are not limited thereto. The intermediate substrate layer 302 may be an inorganic insulating layer, but is not limited thereto. The intermediate substrate layer 302 may prevent electric charges charged in the first substrate 301, which is a polyimide layer, from affecting transistors disposed on the second substrate 303, which is also a polyimide layer.

In addition, the intermediate substrate layer 302 may block moisture from penetrating upward through the first substrate 301. For example, the intermediate substrate layer 302 may be formed as a single layer or multiple layers of silicon nitride (SiNx) or silicon oxide (SiOx), or may be formed as a double layer of silicon dioxide (SiO2) and silicon nitride (SiNx), but is not limited thereto.

The transistor portion may include insulating layers 311, 312, 313, 321, 322, and 323 on the substrate 111, thin-film transistors TFT1 and TFT2, a storage capacitor CST, and various electrodes or signal lines.

The thin-film transistors TFT1 and TFT2 included in the transistor portion may include a first thin-film transistor TFT1 and a second thin-film transistor TFT2.

The first thin-film transistor TFT1 may include a first active layer ACT1, a first electrode E1a, a second electrode E1b, and a third electrode E1c.

The first electrode E1a is a gate electrode, and the second electrode E1b and the third electrode E1c may be a drain electrode or a source electrode. Hereinafter, for convenience of explanation, the first electrode E1a is referred to as the first gate electrode E1a, the second electrode E1b as a first source electrode E1b, and the third electrode E1c as the first drain electrode E1c. However, the embodiments of the present disclosure are not limited thereto.

The first active layer ACT1 may include a first semiconductor material. For example, the first semiconductor material may include an oxide semiconductor, amorphous silicon, polysilicon, or low-temperature polysilicon (LTPS), but is not limited thereto. The first thin-film transistor TFT1 may be implemented as a p-channel transistor or an n-channel transistor, but is not limited thereto.

The second thin-film transistor TFT2 may include a second active layer ACT2, a fourth electrode E2a, a fifth electrode E2b, and a sixth electrode E2c.

The fourth electrode E2a is a gate electrode, and the fifth electrode E2b and the sixth electrode E2c may be a drain electrode or a source electrode. Hereinafter, for convenience of explanation, the fourth electrode E2a is referred to as the second gate electrode E2a, the fifth electrode E2b as the second source electrode E2b, and the sixth electrode E2c as the second drain electrode E2c. However, the embodiments of the present disclosure are not limited thereto.

A second active layer ACT2 may include a second semiconductor material. For example, the second semiconductor material may include an oxide semiconductor, amorphous silicon, polysilicon, or low-temperature polysilicon (LTPS), but is not limited thereto. The second thin-film transistor TFT2 may be implemented as a p-channel transistor or an n-channel transistor, but is not limited thereto.

The types of semiconductor materials of the first active layer ACT1 of the first thin-film transistor TFT1 and the second active layer ACT2 of the second thin-film transistor TFT2 may be as follows.

For example, the first active layer ACT1 of the first thin-film transistor TFT1 and the second active layer ACT2 of the second thin-film transistor TFT2 may include an oxide semiconductor material or a low-temperature polysilicon semiconductor material.

In FIG. 2, the second thin-film transistor TFT2 connected to the pixel electrode PE of the light-emitting device ED may be a driving transistor DT or another transistor different from the driving transistor DT, depending on the configuration of the sub-pixel circuit SPC. For example, it may be a light-emission control transistor connected between the driving transistor DT and the light-emitting device ED.

The second active layer ACT2 of the second thin-film transistor TFT2 may be positioned higher from the substrate 111 than the first active layer ACT1 of the first thin-film transistor TFT1.

A first buffer layer 311 may be disposed under the first active layer ACT1 of the first thin-film transistor TFT1, and a second buffer layer 321 may be disposed under the second active layer ACT2 of the second thin-film transistor TFT2. For example, the first active layer ACT1 of the first thin-film transistor TFT1 may be positioned on the first buffer layer 311, and the second active layer ACT2 of the second thin-film transistor TFT2 may be positioned on the second buffer layer 321. The second buffer layer 321 may be positioned higher than the first buffer layer 311.

The storage capacitor CST may be disposed within various metal layers in the display panel 110. For example, the storage capacitor CST may include a first capacitor electrode CAPE1 and a second capacitor electrode CAPE2.

The light-emitting device portion may include a plurality of light-emitting devices ED disposed on a planarization layer 330. Each of the plurality of light-emitting devices ED may include a pixel electrode PE, an intermediate layer EL, and a common electrode CE.

The encapsulation portion may include an encapsulation layer 200 on the plurality of light-emitting devices ED. The encapsulation layer 200 may be a single layer or multiple layers, but the embodiments of the present disclosure are not limited thereto. The encapsulation portion may further include at least one dam DAM for preventing overflow of a material forming the encapsulation layer 200 in addition to the encapsulation layer 200. In particular, when a second encapsulation layer 342 included in the encapsulation layer 200 is an organic encapsulation layer composed of an organic material, the dam DAM may prevent overflow of the organic material.

Hereinafter, the structure or vertical structure of the display panel 110 according to embodiments of the present disclosure will be described in more detail with reference to FIG. 2.

Referring to FIG. 2, the first buffer layer 311 may be disposed on the substrate 111. The first buffer layer 311 may be a single layer or multiple layers, but the embodiments of the present disclosure are not limited thereto. When the first buffer layer 311 is a multilayer, the first buffer layer 311 may include a lower buffer layer 311a and an upper buffer layer 311b.

The first active layer ACT1 of the first thin-film transistor TFT1 may be disposed on the first buffer layer 311. The first active layer ACT1 may include a channel region in which a channel is formed, a source connection region on one side of the channel region, and a drain connection region on the other side of the channel region.

A first gate insulating layer 312 may be disposed on the first active layer ACT1 of the first thin-film transistor TFT1. A first gate electrode E1a of the first thin-film transistor TFT1 may be disposed on the first gate insulating layer 312. A first interlayer insulating layer 313 may be disposed on the first gate electrode E1a of the first thin-film transistor TFT1. Here, the metal layer in which the first gate electrode E1a of the first thin-film transistor TFT1 is disposed may be referred to as a first gate metal layer.

The second buffer layer 321 may be disposed on the first interlayer insulating layer 313.

The second active layer ACT2 of the second thin-film transistor TFT2 may be disposed on the second buffer layer 321. The second active layer ACT2 may include a channel region in which a channel is formed, a source connection region on one side of the channel region, and a drain connection region on the other side of the channel region.

A second gate insulating layer 322 may be disposed on the second active layer ACT2 of the second thin-film transistor TFT2. A second gate electrode E2a of the second thin-film transistor TFT2 may be disposed. A second interlayer insulating layer 323 may be disposed on the second gate electrode E2a of the second thin-film transistor TFT2. Here, the second gate electrode E2a of the second thin-film transistor TFT2 may be referred to as a second gate metal layer.

A first source electrode E1b and a first drain electrode E1c of the first thin-film transistor TFT1 and a second source electrode E2b and a second drain electrode E2c of the second thin-film transistor TFT2 may be disposed on the second interlayer insulating layer 323.

The first source electrode E1b and the first drain electrode E1c of the first thin-film transistor TFT1 may be respectively connected to the source connection region and the drain connection region of the first active layer ACT1 through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin-film transistor TFT2 may be respectively connected to the source connection region and the drain connection region of the second active layer ACT2 through holes in the second interlayer insulating layer 323 and the second gate insulating layer 322.

The first source electrode E1b and the first drain electrode E1c of the first thin-film transistor TFT1 and the second source electrode E2b and the second drain electrode E2c of the second thin-film transistor TFT2 may include a first source-drain metal and may be disposed in a first source-drain metal layer.

Referring to FIG. 2, for example, the storage capacitor CST may be formed by a first capacitor electrode CAPE1 and a second capacitor electrode CAPE2. In some cases, the storage capacitor CST may be formed by three or more capacitor electrodes, and may be in a form in which two or more capacitors are connected in parallel.

Each of the first capacitor electrode CAPE1 and the second capacitor electrode CAPE2 may be disposed in various metal layers disposed in the display panel 110.

For example, the first capacitor electrode CAPE1 may include the same first gate metal as the first gate electrode E1a of the first thin-film transistor TFT1 on the first gate insulating layer 312, and may be disposed in a first gate metal layer, but the embodiments of the present disclosure are not limited thereto. For example, the second capacitor electrode CAPE2 may be disposed on the first interlayer insulating layer 313.

The second source electrode E2b of the second thin-film transistor TFT2 may be electrically connected to the second capacitor electrode CAPE2 through holes in the second interlayer insulating layer 323, the second gate insulating layer 322, and the second buffer layer 321.

Referring to FIG. 2, the transistor portion may further include a first shield pattern BSM1 disposed on the substrate 111. The first shield pattern BSM1 may overlap with the first active layer ACT1 of the first thin-film transistor TFT1. The first shield pattern BSM1 may be disposed below the first active layer ACT1 of the first thin-film transistor TFT1. For example, the first shield pattern BSM1 may be disposed between the substrate 111 and the first buffer layer 311 or between the lower buffer layer 311a and the upper buffer layer 311b.

The transistor portion may further include a second shield pattern BSM2 disposed on the substrate 111. The second shield pattern BSM2 may overlap with the second active layer ACT2 of the second thin-film transistor TFT2. The second shield pattern BSM2 may be disposed below the second active layer ACT2 of the second thin-film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor CAPE2, but the embodiments of the present disclosure are not limited thereto. In another example, the second shield pattern BSM2 may be disposed in the same first gate metal layer as the first gate electrode E1a of the first thin-film transistor TFT1.

The planarization layer 330 may be disposed on the first thin-film transistor TFT1 and the second thin-film transistor TFT2 and may be disposed below the light-emitting device ED. The planarization layer 330 may be an organic insulating layer including an organic insulating material.

For example, the planarization layer 330 may be configured as a single layer. In another example, the planarization layer 330 may include two layers. The planarization layer 330 may include a first planarization layer 331 and a second planarization layer 332. In another example, the planarization layer 330 may include three or more layers. The embodiments of the present disclosure are not limited thereto.

Referring to FIG. 2, a connection electrode RE may be disposed on the first planarization layer 331. The connection electrode RE may electrically connect the second source electrode E2b of the second thin-film transistor TFT2 and the pixel electrode PE.

The connection electrode RE may be electrically connected to the second source electrode E2b of the second thin-film transistor TFT2 through a hole in the first planarization layer 331. The second source electrode E2b of the second thin-film transistor TFT2 may be electrically connected to the second capacitor electrode CAPE2 of the storage capacitor CST.

The connection electrode RE may be disposed in a second source-drain metal layer on the first planarization layer 331 and may include a second source-drain metal.

A second planarization layer 332 may be disposed on the connection electrode RE.

Referring to FIG. 2, the light-emitting device portion may be disposed on the second planarization layer 332. The light-emitting device ED may be formed on the second planarization layer 332. The light-emitting device ED may include a pixel electrode PE, an intermediate layer EL, and a common electrode CE. A light-emission area of the light-emitting device ED may be formed in a region where the pixel electrode PE, the intermediate layer EL, and the common electrode CE are overlapped and come into contact.

The pixel electrode PE may be disposed on the second planarization layer 332. The pixel electrode PE may be electrically connected to the connection electrode RE through a hole in the second planarization layer 332.

A bank 340 may be disposed on the pixel electrode PE. An opening of the bank 340 may expose a portion of the pixel electrode PE to form a light-emission area. The opening of the bank 340 may overlap a portion of the pixel electrode PE.

For example, the bank 340 may be formed of a material including a black pigment or an organic material such as benzocyclobutene resin, polyimide resin, acrylic resin, or a photosensitive polymer, but the embodiments of the present disclosure are not limited thereto. When the bank 340 is formed of a material including a black pigment or a black dye, it may be a black bank. When the bank 340 is formed of a material including a black pigment or a black dye, external light or reflected external light may be blocked, thereby improving the luminance of the display device.

The intermediate layer EL of the light-emitting device ED may be disposed on the portion of the pixel electrode PE and the bank 340. The common electrode CE may be disposed on the intermediate layer EL.

Referring to FIG. 2, the encapsulation portion may be disposed on the light-emitting device portion and may be located on the common electrode CE. The encapsulation portion may include an encapsulation layer 200 formed on the common electrode CE.

The encapsulation layer 200 may prevent moisture or oxygen from penetrating into the light-emitting device ED. For example, the encapsulation layer 200 may prevent moisture or oxygen from penetrating into the organic material included in the intermediate layer EL of the light-emitting device ED. The encapsulation layer 200 may be formed as a single layer or multiple layers, but the embodiments of the present disclosure are not limited thereto.

For example, the encapsulation layer 200 may include a first encapsulation layer 341, a second encapsulation layer 342, and a third encapsulation layer 343, but the embodiments of the present disclosure are not limited thereto. For example, the first encapsulation layer 341 and the third encapsulation layer 343 may include an inorganic encapsulation layer, and the second encapsulation layer 342 may include an organic encapsulation layer, but the embodiments of the present disclosure are not limited thereto.

The display panel 110 according to embodiments of the present disclosure may include a built-in touch sensor. In this case, the display panel 110 according to embodiments of the present disclosure may include a touch sensor layer 210 formed on the encapsulation layer 200.

Referring to FIG. 2, the touch sensor layer 210 may include a plurality of touch electrodes TE corresponding to the touch sensor and may include at least one touch metal layer for forming the plurality of touch electrodes TE.

For example, the touch sensor layer 210 may include a first touch metal layer on which a plurality of first touch metals TM1 are disposed and a second touch metal layer on which a plurality of second touch metals TM2 are disposed, in order to form the plurality of touch electrodes TE. In this case, the touch sensor layer 210 may further include a touch interlayer insulating layer 352 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2 that are sensor metals. For example, two or more second touch metals TM2 and at least one first touch metal TM1 may constitute a first touch electrode TE1. In this case, two or more second touch electrodes TE2 may be electrically connected by at least one first touch metal TM1.

In another example, the first touch metal layer may be a sensor metal layer, and the second touch metal layer may be a bridge metal layer. In this case, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1 that are sensor metals.

In another example, each of the first touch metal layer and the second touch metal layer may be a sensor metal layer and a bridge metal layer. For example, the first touch metal layer may be both a sensor metal layer and a bridge metal layer, and the second touch metal layer may be both a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 2, the touch sensor layer 210 may further include a touch buffer layer 351 disposed on the encapsulation layer 200. The touch buffer layer 351 may be disposed between the encapsulation layer 200 and the touch metal layers. For example, the first touch metal layer may be disposed on the touch buffer layer 351, and the touch interlayer insulating layer 352 may be disposed on the first touch metal layer.

Referring to FIG. 2, the touch sensor layer 210 may further include a touch protection layer 353 disposed to cover the touch metal layers. For example, the touch protection layer 353 may be disposed on the second touch metal layer.

For example, the touch buffer layer 351 may be an inorganic layer including an inorganic insulating material or an organic layer including an organic insulating material, the touch interlayer insulating layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulating layer 352 may be extended from the display area DA to the non-display area NDA. The touch protection layer 353 may be extended from the display area DA to the non-display area NDA.

The touch routing line TL may electrically connect the touch electrodes TE and a touch pad TP. The touch routing line TL may be configured from at least one of the first touch metal TM1 and the second touch metal TM2.

For example, one touch routing line TL may include a plurality of wiring sections, and each of the plurality of wiring sections may be a single wiring section or a dual wiring section. Here, a single wiring section may be a section with one signal path, and a dual wiring section may be a section with two signal paths connected in parallel.

The touch routing line TL may be disposed along an inclined surface of the encapsulation layer 200 and may extend to the touch pad TP through the top of the dam(s) DAM1 and DAM2.

The touch buffer layer 351 may have an opening that exposes at least a part of the touch pad TP. The touch routing line TL may be electrically connected to the touch pad TP through the opening of the touch buffer layer 351. The touch interlayer insulating layer 352 may be disposed on the touch routing line TL and may extend to the region where the touch pad TP is disposed. The touch protection layer 353 may be disposed only in the display area DA, or may be extended to the non-display area NDA and also disposed on the touch routing line TL. In some cases, the touch protection layer 353 may be further extended to the top of the touch pad TP.

Each of the plurality of touch electrodes TE may be a mesh-type electrode having a plurality of openings. In this case, each of the plurality of touch electrodes TE may be configured from at least one of the second touch metals TM2. However, the embodiments of the present disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected via at least one first touch metal TM1 that is a bridge metal. For example, two second touch metals TM2 spaced apart from each other may be electrically connected by a first touch metal TM1 to form one first touch electrode TE1.

Referring to FIG. 2, the plurality of first touch metals TM1 and the plurality of second touch metals TM2 may be disposed not to overlap with the light-emitting device ED. The plurality of first touch metals TM1 and the plurality of second touch metals TM2 may overlap with the bank 340. Accordingly, the light-emission efficiency of the light-emitting device ED may be improved.

Referring to FIG. 2, the touch routing line TL may connect the touch pad TP disposed in a pad area PA in the second non-display area NDA2 and the first touch electrode TE1 disposed in the display area DA. To this end, the touch routing line TL may be disposed across the second non-display area NDA2, the bending area BA, and the first non-display area NDA1.

The touch routing line TL may include a first wiring section TLa, a second wiring section TLb, and a third wiring section TLc. For example, the touch routing line TL may include the first wiring section TLa and the second wiring section TLb disposed in the first non-display area NDA1 and the second non-display area NDA2, and the third wiring section TLc disposed in the bending area BA. The third wiring section TLc may connect the first wiring section TLa and the second wiring section TLb.

The first wiring section TLa of the touch routing line TL may be a single wiring section and may further include a third touch metal layer in which a third touch metal TM3 is disposed.

The first wiring section TLa of the touch routing line TL may extend along the inclined surface of the encapsulation layer 200 and may be disposed via the top of at least one of the dams DAM1 and DAM2.

For example, the first wiring section TLa of the touch routing line TL may be connected to the third wiring section TLc of the touch routing line TL through at least one of the first touch metal layer and the second touch metal layer.

The second wiring section TLb of the touch routing line TL may include at least one of the first touch metal layer in which the first touch metal TM1 is disposed and the second touch metal layer in which the second touch metal TM2 is disposed.

For example, the second wiring section TLb of the touch routing line TL may be electrically connected to the touch pad TP through a contact hole (opening) penetrating the second planarization layer 332, the touch buffer layer 351, and the touch interlayer insulating layer 352.

For example, the third wiring section TLc of the touch routing line TL may be connected to the second wiring section TLb of the touch routing line TL.

The third wiring section TLc of the touch routing line TL may include a metal layer different from the first to third touch metal layers in which the first to third touch metals TM1, TM2, and TM3 are disposed.

The touch pad TP may be electrically connected to the second wiring section TLb of the touch routing line TL and may include a metal layer different from the first to third touch metal layers.

Referring to FIG. 2, the display panel 110 of the display device according to embodiments of the present disclosure may further include a common voltage line VSSL to which a common voltage VSS is applied and a connection pattern for connecting the common electrode CE and the common voltage line VSSL.

For example, the connection pattern may include a first connection pattern CP1 and a second connection pattern CP2.

For example, the first connection pattern CP1 may connect the common electrode CE and the second connection pattern CP2, and the second connection pattern CP2 may connect the first connection pattern CP1 and the common voltage line VSSL, but is not limited thereto.

For example, the first connection pattern CP1 may include the same material as the pixel electrode PE. The second connection pattern CP2 may include the same material as the connection electrode RE.

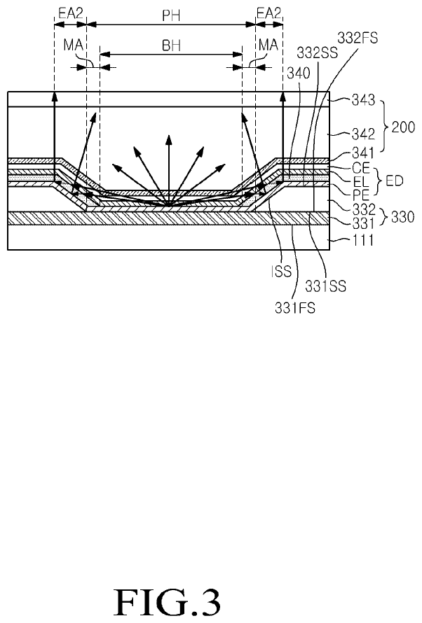

FIG. 3 is a cross-sectional view of a display panel 110 according to embodiments of the present disclosure.

Referring to FIG. 3, the first planarization layer 331 is disposed on the substrate 111. The top surface of the first planarization layer 331 is a surface parallel to the substrate 111. Other layers may be disposed between the substrate 111 and the first planarization layer 331. The first planarization layer 331 may alleviate the height differences among the substrate 111 or layers disposed on the substrate 111. The first planarization layer 331 may be formed of one selected from an acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The second planarization layer 332 having an opening PH may be disposed on the first planarization layer 331. The first planarization layer 331 and the second planarization layer 332 may be integrally formed. The first planarization layer 331 and the second planarization layer 332 together may be referred to as a planarization layer 330. The first planarization layer 331 and the second planarization layer 332 may be formed of the same material and may be formed simultaneously through the same process, for example, a mask process, but are not limited thereto. The second planarization layer 332 includes a top surface and a side surface. The top surface of the second planarization layer 332 is a surface positioned at the topmost part of the second planarization layer 332 and may be substantially parallel to the top surface of the first planarization layer 331 or the substrate 111. The side surface of the second planarization layer 332 may have an inclined shape extending from the top surface toward the first planarization layer 331.

In FIG. 3, the planarization layer 330 is described as including the first planarization layer 331 and the second planarization layer 332, but the detailed structure of the planarization layer 330 is not limited to the first and second planarization layers and may be variously defined.

Referring to FIG. 3, the light-emitting device ED may be disposed on the first planarization layer 331. The light-emitting device ED may include a pixel electrode PE disposed on the first planarization layer 331 and the second planarization layer 332, an intermediate layer EL disposed on the pixel electrode PE, and a common electrode CE disposed on the intermediate layer EL.

The pixel electrode PE may be disposed on the first planarization layer 331 within the opening PH of the second planarization layer 332 and may extend along an inner side surface of the second planarization layer 332. The pixel electrode PE may be disposed on the top surface of the first planarization layer 331, the inner side surface of the second planarization layer 332, and the top surface of the second planarization layer 332. Accordingly, the pixel electrode PE may have a flat top surface on the top surfaces of the first planarization layer 331 and the second planarization layer 332 and may have an inclined top surface on the side surface of the second planarization layer 332.

The pixel electrode PE may be composed of a reflective layer and a transparent conductive layer disposed on the reflective layer. Since the display device according to an embodiment of the present disclosure is a top emission type light-emitting display device, the reflective layer may reflect light emitted from the light-emitting device ED toward the top.

The reflective layer may be made of a metal material. For example, the reflective layer may be made of a metal material such as aluminum (Al), silver (Ag), copper (Cu), or magnesium—silver alloy (Mg:Ag), but is not limited thereto.

Referring to FIG. 3, a bank 340 having a bank hole BH smaller than the opening PH may be disposed on the pixel electrode PE. The bank 340 includes a top surface and side surfaces. The top surface of the bank 340 is a surface located at the topmost part of the bank 340 and may be substantially parallel to the second planarization layer 332. The side surface of the bank 340 may have an inclined shape from the top surface toward the first planarization layer 331. The bank hole BH region may correspond to a main light-emission area.

The bank 340 may be made of an organic or inorganic material. For example, when the bank 340 is made of an organic material, it may be formed of polyimide, acrylic, or benzocyclobutene-based resin. When the bank layer is made of an inorganic material, it may be formed of amorphous silicon, silicon oxide, silicon nitride, or silicon oxynitride, but is not limited thereto.

The intermediate layer EL may be disposed on the pixel electrode PE and the bank 340. For example, in the bank hole BH, the intermediate layer EL may be disposed on the pixel electrode PE, and in a region outside the bank hole BH, it may be disposed on the bank 340.

As the intermediate layer EL is disposed on the bank 340 outside the bank hole BH, the intermediate layer EL may also be disposed in conformity with the shape of the bank 340. Accordingly, the intermediate layer EL may have a flat top surface on the pixel electrode PE within the bank hole BH and on the bank 340 outside the bank hole BH, and may have an inclined top surface on the side surface of the bank 340.

The intermediate layer EL may be a layer for emitting light of a specific color and may include at least one of a red emission layer, a green emission layer, a blue emission layer, and a white emission layer. The intermediate layer EL may further include various layers such as a hole transport layer, a hole injection layer, a hole blocking layer, an electron injection layer, an electron blocking layer, and an electron transport layer. The intermediate layer EL may be an organic emission layer made of an organic material but is not limited thereto. For example, the intermediate layer EL may be a quantum dot emission layer or a micro-LED.

The common electrode CE may be disposed on the intermediate layer EL. The common electrode CE may supply electrons to the intermediate layer EL. The common electrode CE may be made of a transparent conductive oxide such as indium tin oxide (ITO), indium zinc oxide (IZO), indium tin zinc oxide (ITZO), zinc oxide (ZnO), or tin oxide (TO), or an ytterbium (Yb) alloy. The common electrode CE may also be made of a metal material such as silver (Ag), copper (Cu), or a magnesium—silver alloy (Mg:Ag), or a metal material with a very thin thickness. Since the display device is a top emission type, the common electrode CE may have a very thin thickness such that its refractive index does not affect the propagation of light.

As the common electrode CE is disposed on the intermediate layer EL outside the bank hole BH, the common electrode CE may also be disposed in conformity with the shape of the bank 340. Accordingly, the common electrode CE may have a flat top surface on the pixel electrode PE within the bank hole BH and on the bank 340 outside the bank hole BH, and may have an inclined top surface on the side surface of the bank 340.

Referring to FIG. 3, the encapsulation portion 200 may be disposed on the light-emitting device ED. The encapsulation portion 200 may be disposed to cover the common electrode CE. The encapsulation portion 200 may protect the intermediate layer EL from moisture or oxygen penetrating from the outside of the display device.

The encapsulation portion 200 may include a first encapsulation layer 341, a second encapsulation layer 342, and a third encapsulation layer 343.

The first encapsulation layer 341 may be disposed on the common electrode CE and may suppress the penetration of moisture or oxygen. The first encapsulation layer 341 may be made of an inorganic material such as silicon nitride (SiNx), silicon oxynitride (SiNxOy), or aluminum oxide (AlyOz), but is not limited thereto.

As the first encapsulation layer 341 is disposed on the common electrode CE, the first encapsulation layer 341 may also be disposed in conformity with the shape of the common electrode CE. Accordingly, the first encapsulation layer 341 may have a flat top surface on the pixel electrode PE within the bank hole region BH and on the bank 140 outside the bank hole BH, and may have an inclined top surface on the side surface of the bank 340.

The second encapsulation layer 342 may be disposed on the first encapsulation layer 341 to planarize its surface. The second encapsulation layer 342 may also cover foreign substances or particles that may occur during the manufacturing process. The second encapsulation layer 342 may be made of an organic material, for example, silicon oxycarbide (SiOxCz), acrylic, or epoxy-based resin, but is not limited thereto.

The third encapsulation layer 343 may be disposed on the second encapsulation layer 342 and may suppress the penetration of moisture or oxygen, similar to the first encapsulation layer 341. The third encapsulation layer 343 may be made of an inorganic material such as silicon nitride (SiNx), silicon oxynitride (SiNxOy), silicon oxide (SiOx), or aluminum oxide (AlyOz), but is not limited thereto. The third encapsulation layer 343 may be made of the same material as the first encapsulation layer 341 or a different material from the first encapsulation layer 341.

Since the display device according to an embodiment of the present disclosure is a top emission type display device, a micro-cavity may be implemented. For example, in the display device according to an embodiment of the present disclosure, by setting the distance between the reflective layer of the pixel electrode PE and the common electrode CE, constructive interference for light emitted from the intermediate layer EL may be implemented to improve light efficiency.

In the display panel 110 according to embodiments of the present disclosure, a portion of the pixel electrode PE may extend along the inclined surface of the second planarization layer 332. This structure is referred to as an optical side mirror (OSM) structure in the present disclosure.

The display panel 110 according to embodiments of the present disclosure may include an optical mirror structure, and thus, a second emission area EA2 may be additionally formed by light reflected from a portion of the pixel electrode PE disposed on the side surface of the second planarization layer 332. That is, the emission area formed in each of the plurality of sub-pixels may include not only a first emission area EA1 but also the second emission area EA2.

Of the total amount of light emitted from the intermediate layer EL, some may be trapped inside the display panel 110 and may not be emitted externally. The ratio of the amount of light that is normally emitted outside the display panel 110 to the total amount of light emitted from the intermediate layer EL is referred to as light extraction efficiency.

According to the optical side mirror (OSM) structure of the display panel 110 according to embodiments of the present disclosure, light extraction efficiency may be improved.

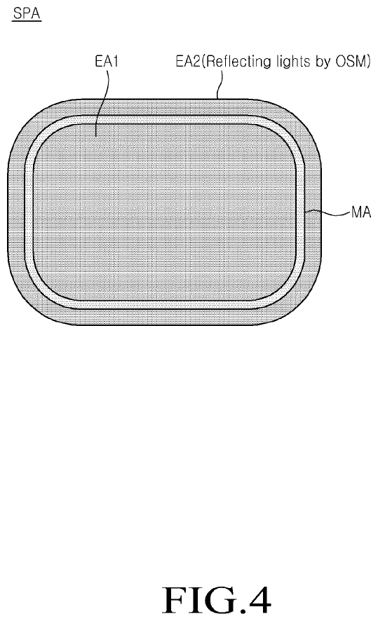

FIG. 4 illustrates light emission in a sub-pixel area SPA according to embodiments of the present disclosure.

As illustrated in FIG. 4, the sub-pixel area SPA may form the first emission area EA1 corresponding to the hole of the bank and the second emission area EA2 surrounding the first emission area EA1. An intermediate area MA optically distinguishable from the first emission area EA1 and the second emission area EA2 may exist between the first emission area EA1 and the second emission area EA2. Alternatively, an intermediate area MA may not exist between the first emission area EA1 and the second emission area EA2.

The first emission area EA1 may be referred to as a main emission area of the opening PH. The first emission area EA1 may correspond to the bank hole BH.

The intermediate area MA may correspond to a region of the opening PH of the second planarization layer 332 excluding the bank hole BH.

The second emission area EA2 may correspond to a region between a starting point and an ending point of the inclined surface of the second planarization layer 332.

The first emission area EA1 may have a first luminance. The second emission area EA2 may have a second luminance lower than the first luminance. The intermediate area MA may have a third luminance lower than the second luminance.

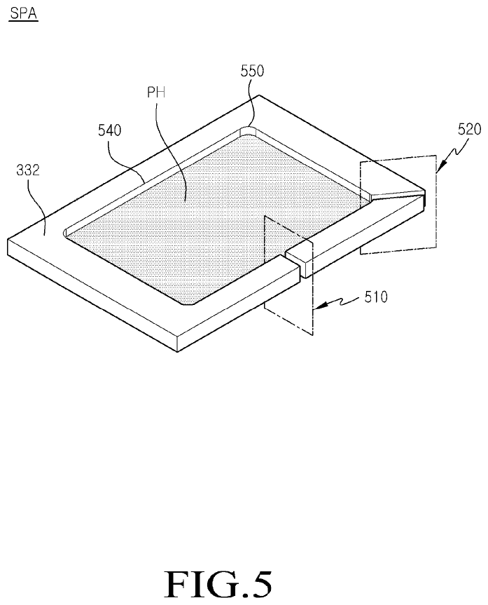

FIG. 5 is a plan view of the sub-pixel area SPA according to embodiments of the present disclosure.

Referring to FIG. 5, the sub-pixel area SPA may include the opening PH and the second planarization layer 332. An edge of the opening PH may include a corner portion 550 and an edge portion 540. The opening PH refers to the opening of the second planarization layer, and hereinafter, the opening PH is used to denote the opening of the second planarization layer.

A curved region included in the edge of the opening PH may correspond to the corner portion 550. A problem may arise in which the cross-sections of the corner portion 550 and the edge portion 540 are formed differently even under the same process conditions. For example, a second inclination angle θ2 of the second planarization layer 332 in the corner portion 550 (also see 520) may be greater than a first inclination angle θ1 of the second planarization layer 332 in the edge portion 540 (also see 510). The distance between the end of the second planarization layer 332 and the end of the bank 340 in the corner portion 550 may be longer than the distance between the end of the second planarization layer 332 and the end of the bank 340 in the edge portion 540.

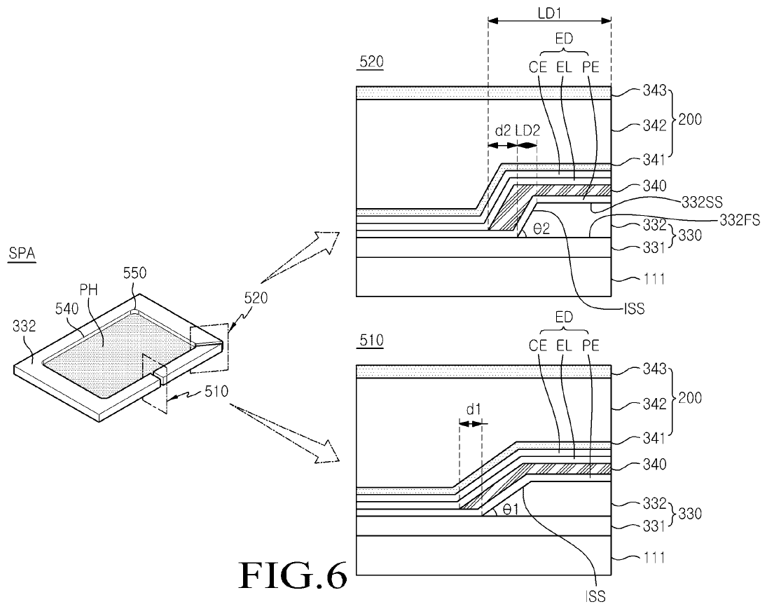

FIG. 6 illustrates cross-sectional views of the corner portion 550 and the edge portion 540 of FIG. 5 according to embodiments of the present disclosure.

Referring to FIG. 6, the structure of the second planarization layer 332 may differ between the corner portion 550 and the edge portion 540. Hereinafter, the structure of the sub-pixel area SPA according to embodiments of the present disclosure will be described in more detail. FIG. 6 includes a corner cross-sectional view 520 and an edge cross-sectional view 510. The edge cross-sectional view 510 of FIG. 6 is the same as described in FIG. 3 and will thus be omitted.

Referring to FIG. 6, in the corner portion 550 corresponding to the curved edge region of the opening PH, the inclination of the second planarization layer 332 may be formed more steeply. A second angle θ2 (also referred to as ‘a second inclination angle θ2’) formed between the first planarization layer 331 and the side surface of the second planarization layer 332 in the corner portion 550 may be greater than a first angle θ1 (also referred to as ‘a first inclination angle θ1’) formed between the first planarization layer 331 and the side surface of the second planarization layer 332 in the edge portion 540 (also see 510).

Referring to the corner cross-sectional view 520, a second separation distance d2 between the end of the second planarization layer 332 and the end of the bank in the corner portion 550 may be greater than a first separation distance d1 between the end of the second planarization layer 332 and the end of the bank 340 in the edge portion 540.

Due to differences in angles and separation distances between the edge portion 540 and the corner portion 550, a phenomenon in which light is not emitted from the corner portion 550 may occur.

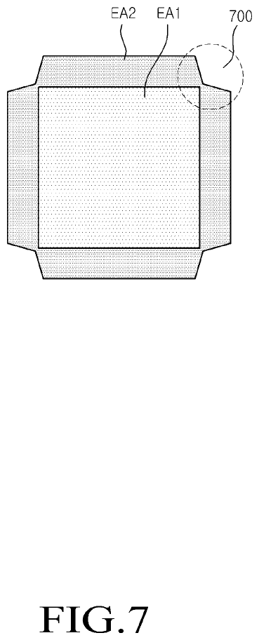

FIG. 7 illustrates light emission in the sub-pixel area SPA according to embodiments of the present disclosure.

Referring to FIG. 7, an issue may arise in which light is not emitted from the corner portion 550 of the second emission area EA2. There may be a difference in the amount of light emitted between the edge portion 540 and the corner portion 550. The corner portion 550 may emit less light than the edge portion 540. As a result, a difference between the edge portion 540 and the corner portion 550 may occur, leading to a deterioration in image quality.

Hereinafter, a structure for improving light emission in the corner portion is described to address this issue.

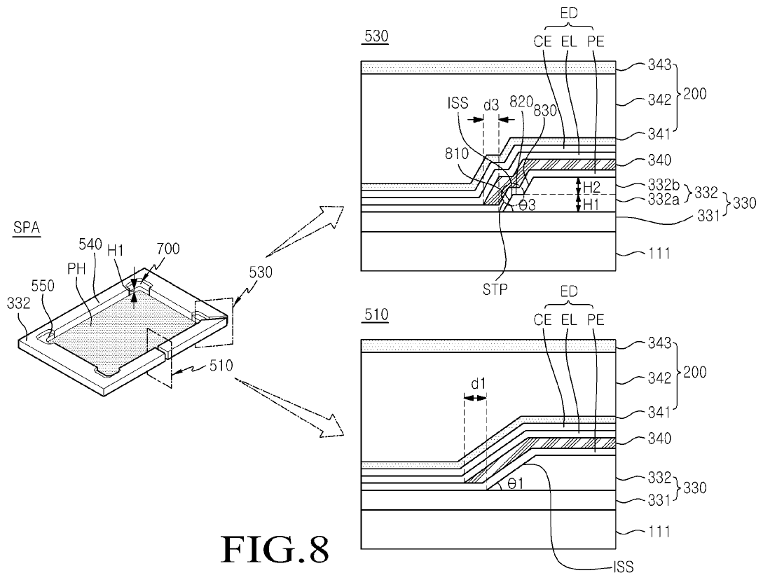

FIG. 8 is a cross-sectional view of the sub-pixel area SPA according to embodiments of the present disclosure.

Referring to FIG. 8, a corner emission improvement structure for solving the emission issue of the corner portion 550 shown in FIG. 4 and FIG. 7 is disclosed.

The edge cross-sectional view 530 of the opening PH of the second planarization layer 332 shown in FIG. 8 is the same as the edge cross-sectional view 510 shown in FIG. 3 and FIG. 6, and thus, the description is omitted..

The corner cross-sectional view 530 of the second planarization layer 332 will be described. The corner cross-sectional view 530 discloses other layers disposed on the second planarization layer 332. The display panel 110 may include a substrate 111, a first planarization layer 331 disposed on the substrate 111, a second planarization layer 332 having an opening PH and disposed on the first planarization layer 331, a pixel electrode PE disposed on the first planarization layer 331 within the opening PH and extending along the inner side surface of the second planarization layer 332, and a bank 340 disposed on the pixel electrode PE and having a hole BH smaller than the opening PH. The edge of the opening PH may include a specific curved region, and a specific portion 700 of the inner side surface of the second planarization layer 332 corresponding to a specific region may have at least one step.

Hereinafter, the term “opening PH” refers to the opening of the second planarization layer, and the term “hole” refers to the hole of the bank, and the two terms are used accordingly.

A detailed description of the cross-sectional view of the corner portion is provided below with reference to FIG. 8. The first planarization layer 331 may be disposed on the substrate 111. The top surface of the first planarization layer 331 may be parallel to the substrate 111. Other layers may be disposed between the substrate 111 and the first planarization layer 331. The first planarization layer 331 may alleviate height differences of the layers disposed on the substrate 111 or the substrate 111 itself. The first planarization layer 331 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The second planarization layer 332 having the opening PH may be disposed on the first planarization layer 331. The second planarization layer 332 includes a top surface and side surfaces. The top surface of the second planarization layer 332 is the topmost surface of the second planarization layer 332 and may be substantially parallel to the top surface of the first planarization layer 331 or the substrate 111. A specific portion of the inner side surface of the second planarization layer 332 may include a first inclined surface 810 extending from the bottom surface of the second planarization layer 332, a first connection surface 820 extending from the first inclined surface 810 and having a gentler slope than the first inclined surface 810, and a second inclined surface 830 extending from the first connection surface 820 and having a steeper slope than the first connection surface 820.

A first height H1 from the start point to the end point of the first inclined surface 810 may differ from a second height H2 from the start point to the end point of the second inclined surface 830.

A specific portion of the inner side surface of the second planarization layer 332 may be recessed inward from a certain height.

The first planarization layer 331 and the second planarization layer 332 may be integrally formed. The combination of the first planarization layer 331 and the second planarization layer 332 may be referred to as the planarization layer 330. The first planarization layer 331 and the second planarization layer 332 may be formed of the same material. The second planarization layer 332 may include steps formed by adjusting the amount of light exposure using a half-tone mask.

Although the planarization layer 330 is described in FIG. 8 as including the first planarization layer 331 and the second planarization layer 332, the detailed configuration of the planarization layer 330 is not limited to the first planarization layer 331 and the second planarization layer 332 and may be variously defined.

Referring to FIG. 8, the light-emitting device ED may be disposed on the first planarization layer 331. The light-emitting device ED may include a pixel electrode PE disposed on the first planarization layer 331 and the second planarization layer 332, an intermediate layer EL disposed on the pixel electrode PE, and a common electrode CE disposed on the intermediate layer EL.

The pixel electrode PE may be disposed on the first planarization layer 331 within the opening PH and may extend along the inner side surface of the second planarization layer 332. The pixel electrode PE may be disposed on the top surface of the first planarization layer 331, the inner side surface of the second planarization layer 332, and the top surface of the second planarization layer 332. Accordingly, the pixel electrode PE may be disposed along the shapes of the first inclined surface 810, the first connection surface 820, and the second inclined surface 830 of the second planarization layer 332 and may have a stepped inclined side surface.

The pixel electrode may be composed of a reflective layer and a transparent conductive layer disposed on the reflective layer. Since the display device according to an embodiment of the present disclosure is a top emission type light-emitting display device, the reflective layer may reflect light emitted from the light-emitting device ED toward the top.

The reflective layer may be made of a metal material. For example, the reflective layer may be made of a metal material such as aluminum (Al), silver (Ag), copper (Cu), or magnesium—silver alloy (Mg:Ag), but is not limited thereto.

Referring to FIG. 8, the bank 340 having a hole smaller than the opening PH may be disposed on the pixel electrode PE. The bank 340 includes a top surface and side surfaces. The top surface of the bank 340 is a surface located at the topmost part of the bank 340 and may be substantially parallel to the second planarization layer 332. The side surface of the bank 340 may have an inclined shape from the top surface toward the first planarization layer 331. The side surface of the bank 340 may be disposed along the shapes of the first inclined surface 810, the first connection surface 820, and the second inclined surface 830 of the second planarization layer 332. The bank 340 may also have steps on its side surface. A portion of the inner side surface of the bank 340 corresponding to one of the steps of the second planarization layer 332 may include at least one step.

The bank may be made of an organic or inorganic material. For example, when the bank 340 is made of an organic material, it may be formed of polyimide, acrylic, or benzocyclobutene-based resin, and when it is made of an inorganic material, it may be formed of amorphous silicon, silicon oxide, silicon nitride, or silicon oxynitride, but is not limited thereto.

The light-emitting device may include an intermediate layer EL disposed on the pixel electrode PE and extending over the bank, and a common electrode CE disposed on the intermediate layer EL. The intermediate layer EL and the common electrode CE may have steps in regions where the second planarization layer 332 has at least one step.

The intermediate layer EL may be disposed on a portion of the pixel electrode PE and a portion of the bank 340. For example, the intermediate layer EL may be disposed on the pixel electrode PE within the bank hole BH and on the bank 340 outside the bank hole BH. As the intermediate layer EL is disposed on the bank 340 outside the bank hole, it may also be disposed along the shape of the bank 340. Thus, the intermediate layer EL may have a flat upper surface on the pixel electrode PE within the bank hole BH and on the bank 340 outside the bank hole. The intermediate layer EL may be disposed along the shape of the first inclined surface 810, the first connection surface 820, and the second inclined surface 830 of the second planarization layer 332 and may include steps on its side surface. A portion of the side surface of the intermediate layer EL corresponding to one of the steps of the second planarization layer 332 may include at least one step.

The intermediate layer EL may be a layer for emitting light of a specific color and may include at least one of a red emission layer, a green emission layer, a blue emission layer, and a white emission layer. In addition, the intermediate layer EL may further include various layers such as a hole transport layer, a hole injection layer, a hole blocking layer, an electron injection layer, an electron blocking layer, and an electron transport layer. The intermediate layer EL may be an organic light-emitting layer made of an organic material, but is not limited thereto. For example, the intermediate layer EL may be a quantum dot emission layer or a micro LED.

The common electrode CE may be disposed on the intermediate layer EL. As the common electrode CE is disposed on the intermediate layer EL outside the bank hole BH, it may also be disposed along the shape of the bank 340. Thus, the common electrode CE may have a flat upper surface on the intermediate layer EL within the bank hole BH and on the bank 340 outside the bank hole BH and may have an inclined side surface on the side surface of the bank 340. The common electrode CE may disposed along the shape of the intermediate layer EL, and a portion of the side surface of the common electrode CE corresponding to one of the steps of the second planarization layer 332 may include at least one step.

The common electrode CE supplies electrons to the intermediate layer EL. The common electrode CE may be formed of a transparent conductive oxide such as indium tin oxide (ITO), indium zinc oxide (IZO), indium tin zinc oxide (ITZO), zinc oxide (ZnO), or tin oxide (TO), or an ytterbium (Yb) alloy. In addition, the common electrode CE may be formed of a metal material such as silver (Ag), copper (Cu), or a magnesium—silver alloy (Mg:Ag), or a very thin metal material. Since the display device is a top emission type, the common electrode CE may be very thin, so the refractive index of the common electrode CE may not affect the propagation of light.

Referring to FIG. 8, the encapsulation portion 200 may be disposed on the light-emitting device ED. The encapsulation portion 200 may be disposed to cover the common electrode CE. The encapsulation portion 200 may protect the intermediate layer EL from moisture or oxygen penetrating from the outside of the display device.

The encapsulation portion 200 may include a first encapsulation layer 341, a second encapsulation layer 342, and a third encapsulation layer 343.

The display panel 110 according to embodiments of the present disclosure may have an optical mirror structure, and an additional second emission area EA2 may be formed by light reflected from a portion of the pixel electrode PE disposed on the side surface of the second planarization layer 332. That is, the light emission area formed in each of the plurality of sub-pixels may include not only the first emission area EA1 but also the second emission area EA2.

Some of the total light emitted from the intermediate layer EL may be trapped inside the display panel 110 and may not be emitted to the outside. The ratio of the amount of light normally emitted to the outside of the display panel 110 to the total amount of light emitted in the intermediate layer EL is referred to as light extraction efficiency.

The display panel 110 according to an embodiment of the present disclosure may increase the ratio of light normally emitted to the outside of the display panel 110 by adjusting the amount of light exposure and forming a step in the second planarization layer 332 at the corner portion 550 of the opening PH. Accordingly, light extraction efficiency may be improved compared to the existing optical side mirror structure.

The display panel 110 according to embodiments of the present disclosure may provide a path where an organic encapsulation layer can be widely applied by forming a step in the second planarization layer 332.

Referring to FIG. 8, the sub-pixel area SPA may include a planarization layer opening PH and the planarization layer 332. The planarization layer opening PH is the opening PH of the planarization layer 332. The planarization layer opening PH may include an edge portion 540 and a corner portion 550.

In one example, the edge of the planarization layer opening PH may be polygonal and may include specific sections corresponding to vertices of the polygon. In another example, the edge of the planarization layer opening PH may have a circular or elliptical shape and may include specific sections 700 corresponding to the circumference of the circle or ellipse.

The edge of the planarization layer opening PH may include a plurality of straight edge portions 540 and a plurality of curved corner portions 550. Each of the plurality of corner portions 550 may correspond to a specific section, and a corner inner side surface of the second planarization layer 332 corresponding to each of the plurality of corner portions 550 may have at least one step, while an edge inner side surface of the second planarization layer 332 corresponding to each of the plurality of edge portions 540 may not have a step.

In each of the plurality of corner portions 550, a third separation distance d3 between the corner inner side surface of the second planarization layer 332 and the inner side surface of the bank 340 may be equal to or greater than a first separation distance d1 between the edge inner side surface of the second planarization layer 332 and the inner side surface of the bank 340 in each of the plurality of edge portions 540. Also, the third separation distance d3 of FIG. 8 may be equal to or less than the second separation distance d2.

In each of the plurality of corner portions 550, a third inclination angle θ3 of the corner inner side surface of the second planarization layer 334 may be equal to or greater than a first inclination angle θ1 of the edge inner side surface of the second planarization layer 334 in each of the plurality of edge portions. The third inclination angle θ3 may be equal to or less than the second inclination angle θ2 in FIG. 6.

The light-emitting area may include the first emission area EA1 corresponding to the hole of the bank and formed by light emitted from the intermediate layer EL, and the second emission area EA2 surrounding the first emission area EA1 and formed by light reflected from the inner side surface of the second planarization layer 332. The second emission area EA2 may include a light-emitting area formed by light reflected from a specific portion.

The display device according to embodiments of the present disclosure may be a mobile display such as a TV, smartphone, or tablet, a wearable display such as a watch, a vehicle display, or a foldable display.

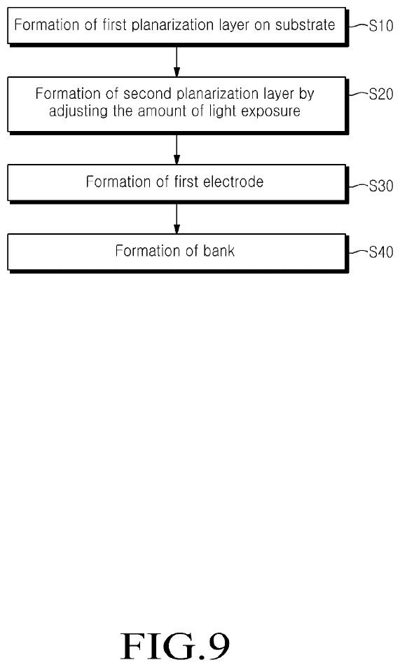

FIG. 9 is a flowchart illustrating the steps of a method for manufacturing the sub-pixel area SPA according to embodiments of the present disclosure.

Referring to FIG. 9, the manufacturing method of the display device may include a step of forming a first planarization layer 331 on a substrate 111, a step of forming a second planarization layer 332 by adjusting the amount of light exposure, a step of forming a pixel electrode PE, and a step of forming a bank 340.

In the step S10 of forming the first planarization layer 331 on the substrate 111, the first planarization layer 331 may be formed on the substrate.

In the step S20 of forming the second planarization layer 332 by adjusting the amount of light exposure, the second planarization layer 332 may be formed on the first planarization layer 331, and an opening PH and a step may be formed the second planarization layer 332 by adjusting the amount of light exposure.

In the step of forming the pixel electrode PE, the pixel electrode PE may be formed to extend from the upper portion of the first planarization layer 331 to the side and upper portions of the second planarization layer 332. The pixel electrode PE may be formed to conform to the shape of the second planarization layer 332 and include a step.

In the step of forming the bank 340, the bank 340 may be formed on the pixel electrode PE. The bank 340 may include a bank hole BH and be formed along the pixel electrode PE to have the same shape. The bank 340 may also have a step similar to the second planarization layer 332. In some examples, the bank may not include a step.

The manufacturing method of the display device may include a step of forming the first planarization layer 331 on the substrate 111, a step of forming the second planarization layer 332 with an opening PH on the first planarization layer 331, a step of forming the pixel electrode PE disposed on the first planarization layer 331 within the opening PH and extending along the side surface of the second planarization layer 332 outside the opening PH, and a step of forming the bank 340 on the pixel electrode PE with a hole smaller than the opening PH. In the step of forming the second planarization layer 332, at least one step may be formed at the corner portion 550 of the inner side surface of the second planarization layer 332 by adjusting the amount of light exposure.

Non-corner portions of the inner side surface of the second planarization layer 332 may not have a step.

The corner portion 550 of the inner side surface of the second planarization layer 332 may include the first inclined surface 810 extending from the bottom surface of the second planarization layer 332, the first connection surface 820 extending from the first inclined surface 810 and having a gentler slope than the first inclined surface 810, and the second inclined surface 830 extending from the first connection surface 820 and having a steeper slope than the first connection surface 820.

In the step of forming the second planarization layer 332, at least one of the first height H1 from the start point to the end point of the first inclined surface 810 and the size of the first connection surface 820 may be adjusted by controlling the amount of light amount.

When using a positive PR for exposure, increasing the amount of light exposure may reduce the first height or increase the size of the first connection surface.

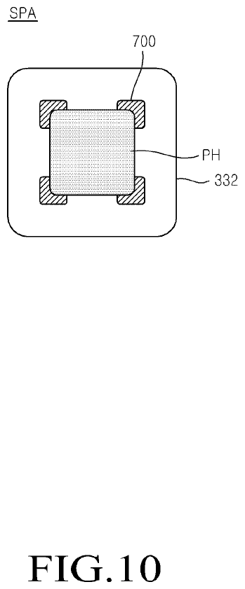

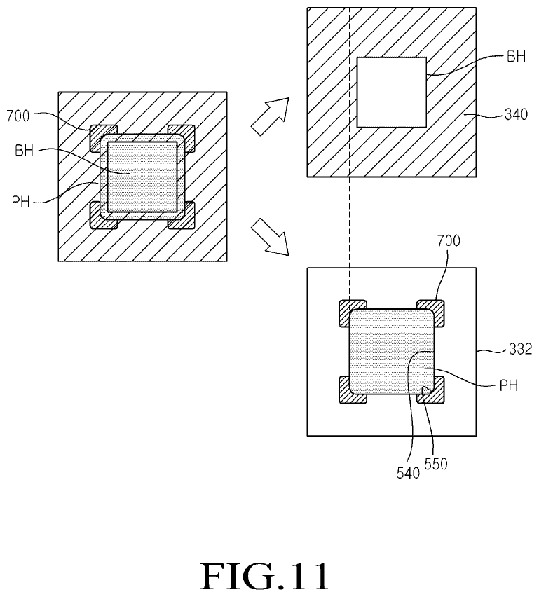

FIG. 10 and FIG. 11 are diagrams illustrating a method for manufacturing the sub-pixel area SPA according to embodiments of the present disclosure.

FIG. 10 describes an example of using positive PR in the exposure process of the second planarization layer. Negative PR may also be used in other examples. Referring to FIGS. 10, 100% exposure may be performed on the opening PH of the second planarization layer 332, and 0% exposure may be performed on regions of the second planarization layer 332 other than the corner portion 550, meaning they are not exposed. The corner portion 550 may be exposed in the range of 0-100%. In one embodiment, 50% exposure may be to the corner portion 550. However, the disclosure is not limited thereto. After the exposure process, an etching process may be performed to etch the second planarization layer 332 and form the opening.

Referring to FIGS. 11, 100% exposure may be applied to some areas of the second planarization layer 332 to form the opening PH. 50% exposure may be applied to the corner portion 550 to form a step in the second planarization layer 332. The edge 540 of the second emission area may be exposed at 0% and may not form a step.

Referring to FIG. 11, the bank 340 may be formed on the second planarization layer 332 with the formed opening PH. Exposure and etching processes may be performed on some areas of the bank 340 to form the bank hole BH. The area of the bank hole BH may be smaller than the area of the second planarization layer 332.

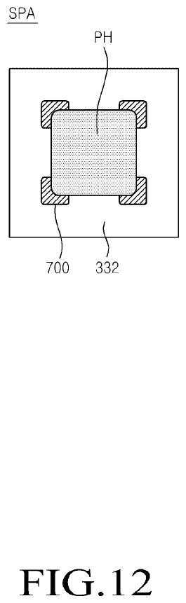

FIG. 12 to FIG. 16 are plan views of the sub-pixel area SPA according to embodiments of the present disclosure.

Referring to FIG. 12, the edge of the opening PH may be rectangular and may include specific sections corresponding to the vertices of the rectangle. For example, the opening PH may have four corner portions 550 corresponding to the four vertices, and the specific portions 700 corresponding to the four corner portions may have steps formed in the second planarization layer 332.

Referring to FIG. 12, the edge of the opening PH may include a curved specific section, and the specific portion 700 corresponding to the specific section of the inner side surface of the second planarization layer 332 may include at least one step. FIG. 12 may include four curved specific portions 700.

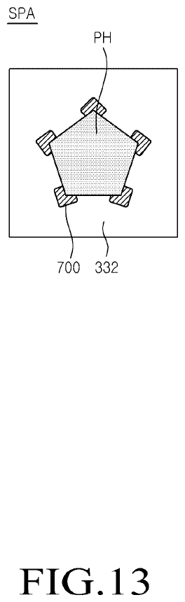

Referring to FIG. 13, the edge of the opening PH may be pentagonal and may include specific sections corresponding to the vertices of the pentagon. For example, the opening PH may have five corner portions 550 corresponding to the five vertices, and the specific portions corresponding to the five corner portions 550 may include steps in the second planarization layer 332.

Referring to FIG. 13, the edge of the opening PH may include a curved specific section, and the specific portion 700 corresponding to the specific section of the inner side surface of the second planarization layer 332 may include at least one step. FIG. 13 may include five curved specific portions 700.

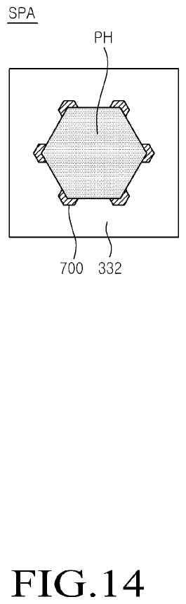

Referring to FIG. 14, the edge of the opening PH may be hexagonal and may include specific sections corresponding to the vertices of the hexagon. For example, the opening PH may have six corner portions 550 corresponding to the six vertices, and the specific portions 700 corresponding to the six corner areas may include steps in the second planarization layer 332.

Referring to FIG. 14, the edge of the opening PH may include a curved specific section, and the specific portion 700 corresponding to a specific section of the inner side surface of the second planarization layer 332 may include at least one step. FIG. 14 may include five curved specific portions 700.

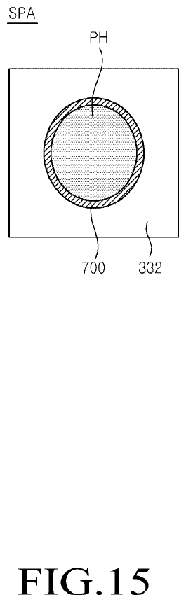

Referring to FIG. 15, the edge of the opening PH may have a circular shape and may include a specific section corresponding to the circumference of the circle. The specific section corresponding to the circumference may have a step in the second planarization layer 332.

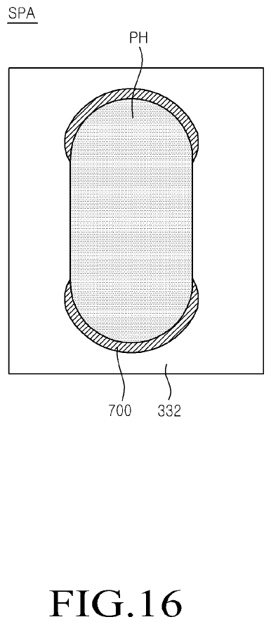

Referring to FIG. 16, the edge of the opening PH may have an elliptical shape and may include a specific section corresponding to the circumference of the ellipse. The specific section corresponding to the circumference may have a step in the second planarization layer 332.

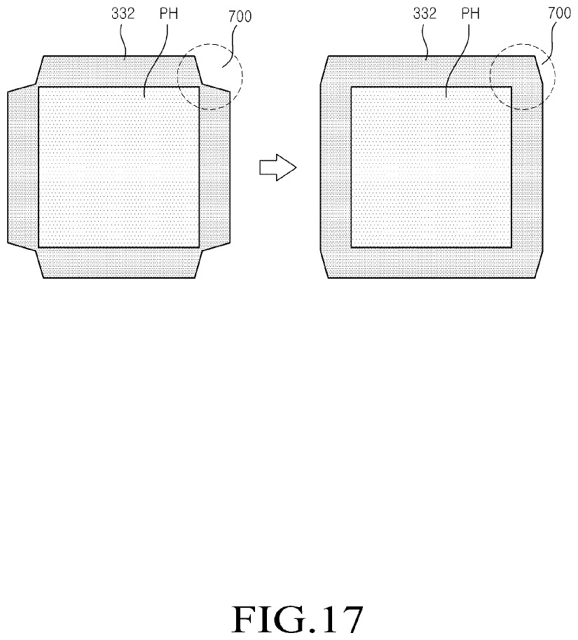

FIG. 17 illustrates the light-emitting appearance of the sub-pixel area SPA according to embodiments of the present disclosure.

Referring to FIG. 17, the corner portion of the left sub-pixel area SPA may not emit light because a step is not formed in the corner portion 550 of the second planarization layer 332. The corner portion of the right sub-pixel area SPA may emit light because a step is formed in the corner portion 550 of the second planarization layer 332. As a result, the sub-pixel area SPA with the step formed in the corner portion may have an increased area of the second emission area EA2, and the light extraction efficiency may be improved.

The display device according to embodiments of the present disclosure may be described as follows.

The display device according to embodiments of the present disclosure may include a substrate, a first planarization layer disposed on the substrate, a second planarization layer disposed on the first planarization layer and having an opening, a pixel electrode disposed on the first planarization layer within the opening and extending along the inner side surface of the second planarization layer, and a bank disposed on the pixel electrode and having a hole smaller than the opening. The edge of the opening may include a curved specific section, and the opening may be defined by the inner side surface of the second planarization layer. A specific portion corresponding to a specific section of the inner side surface of the second planarization layer may have at least one step.

The edge of the opening may be polygonal and may include specific sections corresponding to the vertices of the polygon.

The edge of the opening may have a circular or elliptical shape and may include specific sections corresponding to the circumference of the circle or ellipse.

A portion of the inner side surface of the bank corresponding to at least one step of the second planarization layer may include at least one step.

A specific portion of the inner side surface of the second planarization layer may include a first inclined surface extending from the bottom surface of the second planarization layer, a first connection surface extending from the first inclined surface and having a gentler slope than the first inclined surface 810, and a second inclined surface 830 extending from the first connection surface 820 and having a steeper slope than the first connection surface 820.

In a vertical direction, the first height from the start point to the end point of the first inclined surface may differ from the second height from the start point to the end point of the second inclined surface.

A specific portion of the inner side surface of the second planarization layer may be recessed inward from a certain height.

The edge of the opening may include a plurality of straight edge portions and a plurality of curved corner portions. Each of the plurality of curved corner portions may correspond to a specific section. The corner inner side surface of the second planarization layer corresponding to the plurality of curved corner portions may have at least one step. The edge inner side surface of the second planarization layer corresponding to the plurality of straight edge portions may not have a step.

In each of the plurality of corner portions, the inclination angle of the corner inner side surface of the second planarization layer may be greater than or equal to the inclination angle of the edge inner side surface of the second planarization layer in each of the plurality of straight edge portions.

In each of the plurality of corner portions, the distance between the corner inner side surface of the second planarization layer and the inner side surface of the bank may be greater than or equal to the distance between the edge inner side surface of the second planarization layer and the inner side surface of the bank in each of the plurality of straight edge portions.

The display device may include an intermediate layer disposed on the pixel electrode and extending over the bank, and a common electrode disposed on the intermediate layer. The intermediate layer and the common electrode may have a step in a region where the second planarization layer includes at least one step..

The display device may include a first emission area formed by light emitted from the light-emitting layer corresponding to the hole of the bank and a second emission area surrounding the first emission area and formed by light reflected from the inner side surface of the second planarization layer. The second emission area may include an emission area formed by light reflected from a specific portion.

A method of manufacturing a display device may include forming a first planarization layer on a substrate, forming a second planarization layer with an opening on the first planarization layer, forming a pixel electrode disposed on the first planarization layer within the opening and extending along the side surface of the second planarization layer outside the opening, and forming a bank on the pixel electrode with a hole smaller than the opening. In the step of forming the second planarization layer, at least one step may be formed at a corner portion of the inner side surface of the second planarization layer by adjusting the amount of light exposure.

Non-corner portions of the inner side surface of the second planarization layer may not include a step.

The corner portion of the inner side surface of the second planarization layer may include a first inclined surface extending from the bottom surface of the second planarization layer, a first connection surface extending from the first inclined surface and having a gentler slope than the first inclined surface, and a second inclined surface extending from the first connection surface and having a steeper slope than the first connection surface.

In the step of forming the second planarization layer, at least one of the first height from the start point to the end point of the first inclined surface and the size of the first connection surface may be adjusted by controlling the amount of exposure.

Further embodiments of the present disclosure include the following:

In some embodiments, a display device includes a substrate and a first planarization layer 331 having a first surface 331FS facing the substrate 111 and a second surface 331SS opposite the first surface 331FS. The display device further includes a second planarization layer 332 disposed on the second surface 331SS of the first planarization layer 331. The second planarization layer 332 has a first surface 332FS, a second surface 332SS opposite the first surface 332FS, and an inner side surface ISS extending between the first surface 332FS and the second surface 332SS. A pixel electrode PE is disposed on the second surface of the first planarization layer, along the inner side surface of the second planarization layer, and on the second surface of the second planarization layer. A bank 640 is disposed on the pixel electrode. In some embodiments, when viewed in plan view, the bank has a lateral dimension LD1 greater than or equal to a lateral dimension LD2 of the inner side surface ISS of the second planarization layer 332 and overlaps at least a portion of the second surface of the second planarization layer.

In certain embodiments, the second planarization layer includes an opening defined by a plurality of edge portions and a plurality of corner portions. The edge portions extend along straight segments, while the corner portions interconnect the edge portions and are disposed at curved or angular locations of the opening. The combination of the edge portions and corner portions defines the boundary shape of the opening in plan view.

In some examples, the opening of the second planarization layer has a polygonal shape in plan view. The polygonal shape includes multiple linear edge portions interconnected by corner portions disposed at angular transitions between adjacent edge portions. In some embodiments, the opening overlaps a display area of the substrate such that light emitted from an emission layer disposed within the opening is transmitted outward through the display area.

In alternative embodiments, the opening of the second planarization layer has a curved circumference in plan view. The curved circumference may be circular, elliptical, or otherwise arcuate in shape. The opening having the curved circumference may also overlap a display area of the substrate so that the emission area conforms to a curved or rounded geometry.

In some embodiments, a first inclination angle θ1 is defined between the second surface of the first planarization layer and the inner side surface ISS of the second planarization layer at one of the edge portions, and a second inclination angle θ2 is defined between the second surface of the first planarization layer and the inner side surface ISS of the second planarization layer at one of the corner portions. The second inclination angle θ2 at the corner portion may be greater than the first inclination angle θ1 at the edge portion such that the sidewall of the corner portion is steeper than the sidewall of the edge portion.

In certain embodiments, the second planarization layer includes a lower second planarization layer 332a and an upper second planarization layer 332b disposed on the lower second planarization layer 332a. The lower second planarization layer 332a includes a first inclined surface 810, and the upper second planarization layer 332b includes a second inclined surface 830. A first connection surface 820 extends between the first inclined surface 810 of the lower second planarization layer 332a and the second inclined surface 830 of the upper second planarization layer 332b. In some embodiments, the inner side surface ISS of the second planarization layer 332 may thus include the first inclined surface 810, the second inclined surface 830, and the first connection surface 820 in sequence.

In some examples, the lower second planarization layer 332a has a first height H1 measured from the second surface of the first planarization layer to the first connection surface, and the upper second planarization layer 332b has a second height H2 measured from the first connection surface to the second surface of the second planarization layer. The first height H1 and second height H2 may be different from one another to produce a stepped sidewall structure.

In certain embodiments, the first connection surface 820 extending between the first inclined surface 810 and the second inclined surface 830 is substantially planar. The planar configuration of the first connection surface provides a stable intermediate terrace region between the two inclined surfaces.

In some examples, the inner side surface ISS of the second planarization layer 332 includes the first inclined surface 810, the second inclined surface 830, and the first connection surface 820 such that the inner side surface ISS defines a stepped shape STP. The stepped inner side surface ISS forms a continuous closed contour in plan view and defines multiple emission regions when viewed in cross-section.

In certain embodiments, the second planarization layer has an opening defined by a plurality of edge portions and a plurality of corner portions. The stepped inner side surface may be formed only at the plurality of corner portions, while the plurality of edge portions remain free of stepped features and include a single inclined surface.

In some examples, the continuous closed contour defined by the second planarization layer encompasses a primary emission area (e.g., first emission area EA1) and a secondary emission area (e.g., additional second emission area EA2) disposed adjacent the primary emission area. The secondary emission area may be defined along a stepped sidewall region, while the primary emission area may be disposed within a main opening of the second planarization layer.

In certain embodiments, the stepped contour of the second planarization layer defines at least two emission regions having different luminance levels. For example, a first emission area may be defined along a lower inclined surface adjacent the first planarization layer, and a second emission area may be defined along an upper inclined surface adjacent the second planarization layer. Differences in inclination, separation distance, or reflective geometry between the emission regions may produce differences in luminance.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a first planarization layer disposed on the substrate;
a second planarization layer disposed on the first planarization layer and having an opening, the opening having an edge including a specific curved region;
a pixel electrode disposed on the first planarization layer within the opening and extending along an inner side surface of the second planarization layer; and
a bank disposed on the pixel electrode and having a hole smaller than the opening,
wherein the opening is defined by the inner side surface of the second planarization layer, and
wherein a specific portion of the inner side surface of the second planarization layer corresponding to the specific curved region includes at least one step.

2. The display device according to claim 1, wherein the edge of the opening has a polygonal shape and the specific curved region corresponds to a vertex of the polygon.

3. The display device according to claim 1, wherein the edge of the opening has a circular or elliptical shape and the specific curved region corresponds to a circumference of the circle or ellipse.

4. The display device according to claim 1, wherein a portion of the inner side surface of the bank, corresponding to at least one step of the second planarization layer, includes at least one step.

5. The display device according to claim 1,
wherein the specific portion of the inner side surface of the second planarization layer includes:
a first inclined surface extending from a bottom surface of the second planarization layer;
a first connection surface continuing from the first inclined surface and having a gentler slope than the first inclined surface; and
a second inclined surface continuing from the first connection surface and having a steeper slope than the first connection surface.

6. The display device according to claim 5, wherein a first height from a starting point to an ending point of the first inclined surface is different from a second height from a starting point to an ending point of the second inclined surface.

7. The display device according to claim 1, wherein the specific portion of the inner side surface of the second planarization layer is recessed inward from a selected height.

8. The display device according to claim 1,
wherein the edge of the opening includes a plurality of straight edge portions and a plurality of curved corner portions,
wherein each of the corner portions corresponds to the specific curved region,
wherein a corner inner side surface of the second planarization layer corresponding to each of the plurality of corner portions includes at least one step, and
wherein an edge inner side surface of the second planarization layer corresponding to each of the plurality of edge portions does not include a step.

9. The display device according to claim 1, wherein in each of the corner portions, an inclination angle of the corner inner side surface of the second planarization layer is equal to or greater than an inclination angle of the edge inner side surface of the second planarization layer in each of the plurality of edge portions.

10. The display device according to claim 1, wherein in each of the plurality of corner portions, a separation distance between the corner inner side surface of the second planarization layer and the inner side surface of the bank is equal to or greater than a separation distance between the edge inner side surface of the second planarization layer and the inner side surface of the bank in each of the plurality of edge portions.

11. The display device according to claim 1, further comprising:
an intermediate layer disposed on the pixel electrode and extending over the bank; and
a common electrode disposed on the intermediate layer,
wherein the intermediate layer and the common electrode have a step difference in a region where the second planarization layer includes the at least one step.

12. The display device according to claim 11, further comprising:
a first emission area corresponding to a hole of the bank and formed by light emitted from the intermediate layer; and
a second emission area surrounding the first emission area and formed by light reflected from the inner side surface of the second planarization layer,
wherein the second emission area includes an emission area formed by light reflected from the specific portion.

13. A display device comprising:
a substrate;
a first planarization layer having a first surface and a second surface opposite of the first surface, the first surface of the first planarization layer facing the substrate;
a second planarization layer disposed on the second surface of the first planarization layer, the second planarization layer having a first surface, a second surface, and an inner side surface extending between the first surface and the second surface;
a pixel electrode disposed on the second surface of the first planarization layer and disposed on the inner side surface and the second surface of the second planarization layer; and
a bank disposed on the pixel electrode,
wherein, in plan view, the bank has a lateral dimension greater than or equal to a lateral dimension of the inner side surface of the second planarization layer, and the bank overlaps at least a portion of the second surface of the second planarization layer.

14. The display device of claim 12, wherein the second planarization layer has an opening defined by a plurality of edge portions and a plurality of corner portions.

15. The display device of claim 14, wherein the opening of the second planarization layer has a polygonal shape in a plan view, and
wherein the opening of the second planarization layer overlaps a display area of the substrate.

16. The display device of claim 14, wherein the second planarization layer has an opening, and the opening of the second planarization layer has a curved circumference in a plan view, and
wherein the opening of the second planarization layer overlaps a display area of the substrate.

17. The display device of claim 14, wherein a first inclination angle is defined between the second surface of the first planarization layer and the inner side surface of the second planarization layer at an edge portion of the plurality of edge portions,
wherein a second inclination angle is defined between the second surface of the first planarization layer and the inner side surface of the second planarization layer at a corner portion of the plurality of corner portions, and
wherein the second inclination angle at the corner portion is greater than the first inclination angle at the edge portion.

18. The display device of claim 12, wherein the second planarization layer includes a lower second planarization layer and an upper second planarization layer disposed on the lower second planarization layer,
wherein the lower second planarization layer includes a first inclined surface and the upper second planarization layer includes a second inclined surface, and a first connection surface extending between the first inclined surface and the second inclined surface, and
wherein the inner side surface of the second planarization layer includes the first inclined surface of the lower second planarization layer, the second inclined surface of the upper second planarization layer, and the first connection surface.

19. The display device of claim 18, wherein the lower second planarization layer has a first height measured from the second surface of the first planarization layer to the first connection surface,
wherein the upper second planarization layer has a second height measured from the first connection surface to the second surface of the second planarization layer, and
wherein the first height and second height are different from each other.

20. The display device of claim 18, wherein the first connection surface extending between the first inclined surface and the second inclined surface is substantially planar.

21. The display device of claim 18, wherein the inner side surface of the second planarization layer, having a stepped shape formed by the first inclined surface, the second inclined surface, and the first connection surface, forms a continuous closed contour in a plan view and defines multiple emission regions in a cross-sectional view.

22. The display device of claim 21, wherein the second planarization layer has an opening defined by a plurality of edge portions and a plurality of corner portions, and
wherein the stepped inner side surface is formed only at the plurality of corner portions and not at the plurality of edge portions.

23. The display device of claim 21, wherein the continuous closed contour of the second planarization layer defines a primary emission area surrounded by a secondary emission area.

24. The display device of claim 21, wherein a stepped contour of the second planarization layer defines at least two emission regions having different luminance levels.
